(19) United States
(12) Patent Application Publication
(10) Pub. No.: US 2006/0273373 A1
(43) Pub. Date: Dec. 7, 2006

(54) SEMICONDUCTOR DEVICE

(75) Inventors: Susumu Inoue, Suwa (JP); Yutaka Maruo, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/422,404

(22) Filed: Jun. 6, 2006

(30) Foreign Application Priority Data
Jun. 7, 2005 (JP) 2005-167119

(51) Int. Cl. H01L 29/788

(52) U.S. Cl. 257/315; 257/317; 257/318; 257/E29.129

(57) ABSTRACT

A semiconductor device, includes: a non-volatile memory element, wherein the non-volatile memory element includes: a first region; a second region formed adjacent to the first region; and a third region formed adjacent to the second region; and the non-volatile memory element includes: a semiconductor layer; an isolation insulating layer provided on the semiconductor layer and defines a forming region of the non-volatile memory element; a first diffused layer formed on the semiconductor layer in the first region; a first source region and a first drain region formed on the first diffused layer; a second diffused layer spaced apart from the first diffused layer and formed on the semiconductor layer at a periphery of the first diffused layer and the second region; a third diffused layer formed on the semiconductor layer in the third region; a second source region and a second drain region formed on the third diffused layer; a first insulating layer formed above the semiconductor layer in the forming region of the non-volatile memory element; and a first conductive layer provided above the first insulating layer.

### BACKGROUND

1. Technical Field

The present invention relates to a semiconductor device, and more particularly relates to a semiconductor device including a non-volatile memory element having a floating gate electrode.

2. Related Art

As one of a non-volatile memory device, there is a stacked gate type non-volatile memory device which is made of a floating gate electrode provided via an insulating layer on a semiconductor layer, a control gate electrode provided via the insulating layer on the floating gate electrode, and a source region and a drain region provided on the semiconductor layer. In such a stacked gate type non-volatile memory device, writing and erasing are performed by applying a predetermined voltage to the control gate electrode and the drain region, so that electrons are injected and released in the floating gate electrode.

However, in such a stacked gate type non-volatile memory device, the number of process steps increases as a gate electrode forming process needs to be carried out twice, and a manufacturing process also becomes complicated as a thin film of an insulating layer needs to be formed on the floating gate electrode.

Therefore, a non-volatile memory device in reference with Japanese Unexamined Patent Publication No. Sho 63-166274 has been proposed as the non-volatile memory device which is simple in manufacturing process and low in manufacturing cost compared to the stacked gate type non-volatile memory device. In the non-volatile memory device described in JP-A-63-166274, a control gate is an N-type impurity region in a semiconductor layer, and the floating gate electrode is made of a conductive layer such as a single layer polysilicon layer and the like (hereinafter may be referred to as a ‘single layer gate type non-volatile memory device’). Such a single layer gate type non-volatile memory device may be formed as in the case of a normal CMOS transistor forming process, as there is no need to stack the layers of the gate electrode.

### SUMMARY

An advantage of the present invention is to provide a semiconductor device including a single layer gate type non-volatile memory element having a new structure and the non-volatile memory element with good operating characteristics.

(1) A first semiconductor device according to an aspect of the invention, includes: a semiconductor device including a non-volatile memory element, wherein the non-volatile memory element including a first region, a second region formed adjacent to the first region, and a third region formed adjacent to the second region; and the non-volatile memory element including a semiconductor layer; an isolation insulating layer provided on the semiconductor layer and defines a forming region of the non-volatile memory element; a first diffused layer formed on the semiconductor layer in the first region; a first source region and a first drain region formed on the first diffused layer; a second diffused layer spaced apart from the first diffused layer and also formed on the semiconductor layer at the periphery of the first diffused layer and the second region; a third diffused layer formed on the semiconductor layer in the third region; a second source region and a second drain region formed on the third diffused layer; a first insulating layer formed above the semiconductor layer in the forming region of the non-volatile memory element; and a first conductive layer provided above the first insulating layer.

In the first semiconductor device according to another aspect of the invention, the first diffused layer in which the first source region and the first drain region are formed is provided spaced apart from the second diffused layer. In other words, as the first diffused layer is provided on the semiconductor layer, a junction capacitance is reduced, which enables to increase a breakdown voltage of the first diffused layer.

Further, according to another aspect of the invention, when it is described a certain B layer (hereinafter described as a ‘B layer’) is provided above a certain A layer (hereinafter described as an ‘A layer’), it has both meanings that the B layer is provided directly on the A layer, and the B layer is provided on the A layer via other layer.

The semiconductor device according to another aspect of the invention may further include aspects described below.

(2) In the first semiconductor device according to another aspect of the invention, the first diffused layer may have a first conductivity type; and the second diffused layer may have a second conductivity type.

(3) In the first semiconductor device according to another aspect of the invention, the first source region and the first drain region may have the second conductivity type; and the second source region and the second drain region may have the second conductivity type.

(4) In the first semiconductor device according to another aspect of the invention, the third diffused layer may have the first conductivity type.

(5) In the first semiconductor device according to another aspect of the invention, the first conductive layer may have a protruded part in the second region.

(6) In the first semiconductor device according to another aspect of the invention, a fourth diffused layer, an impurity concentration of which is lower than the first diffused layer, may be formed so as to surround the first diffused layer.

(7) In the first semiconductor device according to another aspect of the invention, the fourth diffused layer may be spaced apart from the second diffused layer.

(8) In the first semiconductor device according to another aspect of the invention, the fourth diffused layer may have the first conductivity type.

(9) The first semiconductor device according to another aspect of the invention may include: a second insulating layer formed above the first conductive layer; and a second conductive layer formed above a region between the first diffused layer and the second diffused layer, and also above the second insulating layer.

(10) The semiconductor device according to another aspect of the invention, includes: the semiconductor device including: the non-volatile memory element, wherein the non-volatile memory element including the first region, the second region formed adjacent to the first region, and the third region formed adjacent to the second region; and the non-volatile memory element including the semiconductor layer; the isolation insulating layer provided on the semiconductor layer and defines the forming region of the non-volatile memory element; the first diffused layer formed on the semiconductor layer in the first region; the first source region and the first drain region formed on the first diffused layer; the second diffused layer formed on the semiconductor layer in the second region; the third diffused layer formed on the semiconductor layer in the third region and having the impurity concentration higher than the first diffused layer; the second source region and the second drain region formed on the third diffused layer; the first insulating layer formed above the semiconductor layer in the forming region of the non-volatile memory element; and the first conductive layer provided above the first insulating layer.

In a second semiconductor device according to another aspect of the invention, the third diffused layer, the impurity concentration of which is higher than the first diffused layer, is provided. In other words, the impurity concentration of the first diffused layer is lower than the third diffused layer. This enables to increase the breakdown voltage of the first diffused layer.

(11) In the semiconductor device according to another aspect of the invention, the first diffused layer may have the first conductivity type; the first source region and the first drain region may have the second conductivity type; the second diffused layer may have the second conductivity type; the third diffused layer may have the first conductivity type; and the second source region and the second drain region may have the second conductivity type.

(12) In the semiconductor device according to another aspect of the invention, the third diffused layer may have the first conductivity type.

(13) In the semiconductor device according to another aspect of the invention, the first conductive layer may have the protruded part in the second region.

(14) In the semiconductor device according to another aspect of the invention, the first diffused layer may come in contact with the second diffused layer.

(15) In the semiconductor device according to another aspect of the invention, the first conductivity type may be an N-type; and the second conductivity type may be a P-type.

### BRIEF DESCRIPTION OF THE DRAWINGS

The invention will be described in reference with the accompanying drawings, wherein like numbers refer to like elements and wherein:

FIG. 1 is a diagram illustrating a semiconductor device according to a first example of a first embodiment.

FIG. 2 is a diagram illustrating the semiconductor device according to the first example of the first embodiment.

FIG. 3 is a diagram illustrating the semiconductor device according to the first example of the first embodiment.

FIG. 4 is a diagram illustrating the semiconductor device according to a second example of the first embodiment.

FIG. 5 is a diagram illustrating the semiconductor device according to the second example of the first embodiment.

FIG. 6 is a diagram illustrating the semiconductor device according to the second example of the first embodiment.

FIG. 7 is a diagram illustrating the semiconductor device according to a second embodiment.

FIG. 8 is a diagram illustrating the semiconductor device according to a third embodiment.

FIG. 9 is a diagram illustrating the semiconductor device according to the third embodiment.

FIG. 10 is a diagram illustrating the semiconductor device according to a fourth embodiment.

FIG. 11 is a diagram illustrating the semiconductor device according to the fourth embodiment.

### DESCRIPTION OF EXEMPLARY EMBODIMENTS

Examples of embodiments of the semiconductor device of the present invention will now be described below in reference with the drawings.

### 1. The First Embodiment

### 1.1 The First Example

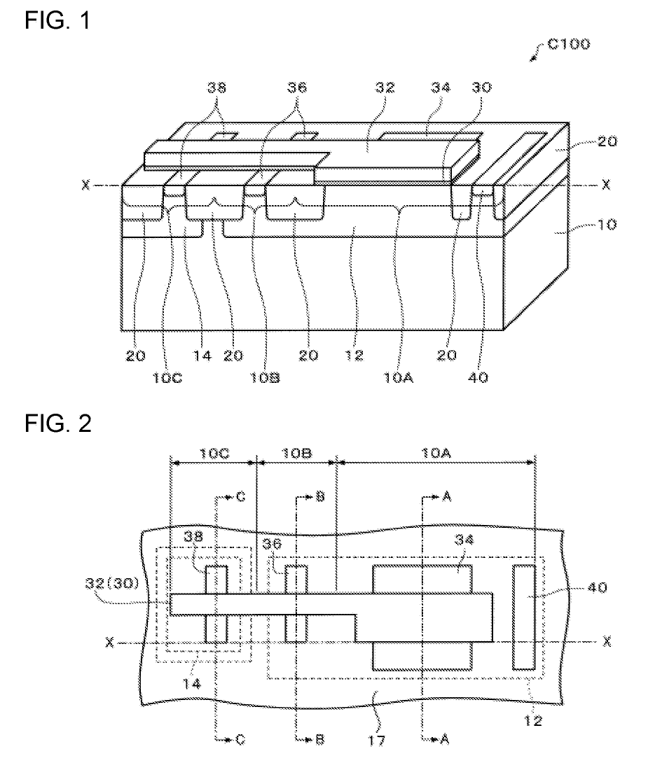

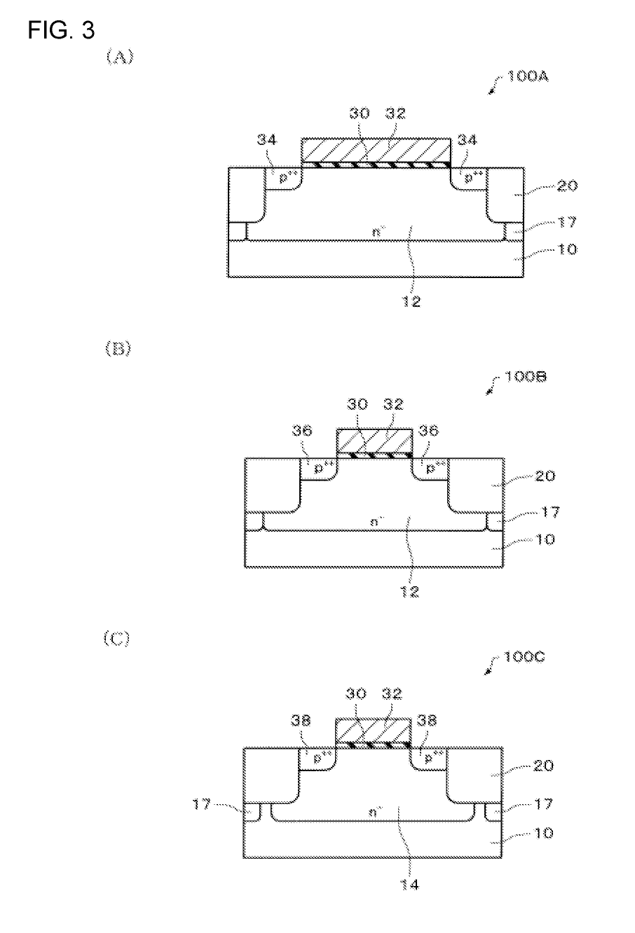

A non-volatile memory element (hereinafter may be referred to as a ‘memory cell’) included in a semiconductor device according to the present embodiment will now be described below in reference with FIGS. 1 to 3. FIG. 1 is a perspective view showing a memory cell C100. FIG. 2 is a plan view showing the disposition of a floating gate electrode 32 and various impurity regions of the memory cell C100. FIG. 3A is a cross section taken along the line A-A of FIG. 2. FIG. 3B is a cross section taken along the line B-B of FIG. 2. FIG. 3C is a cross section taken along the line C-C of FIG. 2. Meanwhile, the line X-X of FIG. 1 is corresponding to the line X-X of FIG. 2.

As shown in FIG. 1, the memory cell C100 according to the present embodiment is provided on a semiconductor layer 10 of P-type. The semiconductor layer 10 is defined into a region 10A (corresponding to a ‘second region’), a region 10B (corresponding to a ‘third region’), and a region 10C (corresponding to a ‘first region’) by an isolation insulating layer 20. A well 12 of N-type, which is one continuous well, is provided in the region 10A and the region 10B (corresponding to an aspect that a ‘second diffused layer’ and a ‘third diffused layer’ are continuous). A well 14 of N-type (corresponding to a ‘first diffused layer’) is provided in the region 10C. The well 12 of N-type and the well 14 of N-type are provided spaced apart from each other. Further, as shown in FIG. 2, a well 17 of P-type which is provided spaced apart, is provided at the periphery of the well 14 of N-type. Normally, a P-type well is formed by injecting an impurity using an inverted mask of the mask that was used during a formation of an N-type well. Therefore, the N-type well and the P-type well are provided in contact with each other. But in the present embodiment, by forming the well 17 of P-type by using a different mask from the inverted mask of the N-type well, the well 14 of N-type and the well 17 of P-type, which is disposed at the periphery, are spaced apart.

The well 12 of N-type in the region 10A functions as a control gate of the memory cell C100. The region 10B is a write section, in which an injection of electrons into the floating gate electrode 32 is performed, which will be described later. The region 10C is an erase section in which electrons injected into the floating gate electrode 32 are to be released. A cross sectional structure of each region will be described later.

An insulating layer 30 is provided on the semiconductor layer 10 in the regions 10A to 10C. On the insulating layer 30, the floating gate electrode 32 is provided across the regions 10A to 10C. Further, in the region 10A, an impurity region 40 of N-type is provided in a region isolated from the region in which the floating gate electrode 32 is provided by the isolation insulating layer 20. The impurity region 40 of N-type may be a contact region for applying a voltage when the write is to be performed to the well 12 of N-type which is the control gate.

In the region 10A, as shown in FIGS. 1 and 2, impurity regions 34 of P-type are provided in a position that the floating gate electrode 32 is sandwiched in between. Similarly, in the region 10B, the floating gate electrode 32 is sandwiched in between impurity regions 36 of P-type, and in the region 10C, the floating gate electrode 32 is sandwiched in between impurity regions 38 of P-type.

Next, a cross sectional structure of each region will be described.

As shown in FIG. 3A, in the region 10A, a transistor 100A of P-channel type is provided. The transistor 100A of P-channel type has the insulating layer 30 provided on the well 12 of N-type, the floating gate electrode 32 provided on the insulating layer 30, and the impurity regions 34 provided in the well 12 of N-type. The impurity regions 34 become the source region and the drain region.

As shown in FIG. 3B, in the region 10B, an MOS transistor 100B of P-channel type to perform the write to the memory cell C100 is provided. The transistor 100B of P-channel type has the insulating layer 30 provided on the well 12 of N-type, the floating gate electrode 32 provided on the insulating layer 30, and the impurity regions 36 provided on the semiconductor layer 10. The impurity regions 36 become the source region and the drain region.

As shown in FIG. 3C, in the region 10C, a transistor 100C of P-channel type is provided. The transistor 100C of P-channel type has the insulating layer 30 provided on the well 14 of N-type, the floating gate electrode 32 provided on the insulating layer 30, and the impurity regions 38 provided in the well 14 of N-type. The impurity regions 38 become the source region and the drain region.

In the semiconductor device according to the first example, a voltage corresponding to a ratio of a capacitance between the floating gate electrode 32 and the well 12 of N-type in the region 10A, and the capacitance between the floating gate electrode 32 and the semiconductor layer 10 of P-type in the region 10B will be applied to the floating gate electrode 32. In other words, the voltage value, which the voltage applied to the control gate multiplied by the capacitance ratio, will be applied to the floating gate electrode 32. Therefore, in order to perform an effective writing, an area overlapping with the floating gate electrode 32 and the well 12 of N-type which is the control gate, is preferably larger compared to the area overlapping with the semiconductor layer 10 and the floating gate electrode 32 in the region 10B where the writing is to be performed. For example, the overlapping area between the floating gate electrode 32 and the well 12 of N-type which is the control gate (the first area) and the overlapping area between the floating gate electrode 32 and the semiconductor layer 10 in the region 10A or 10B (the second area) can be expressed as, a ratio of the first area to the second area equals to the ratio of six to ten through nine to ten (the first area: the second area=6:10 through 9:10).

### 1.2 The Second Example

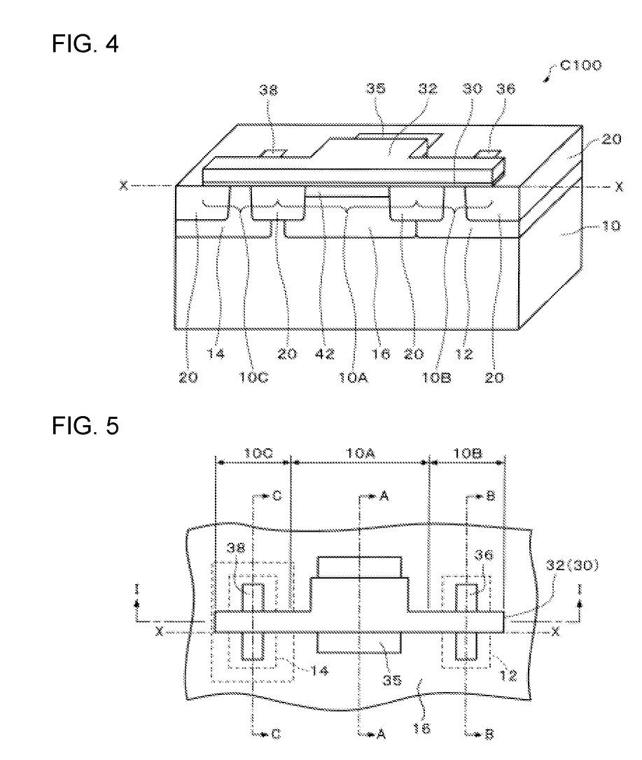

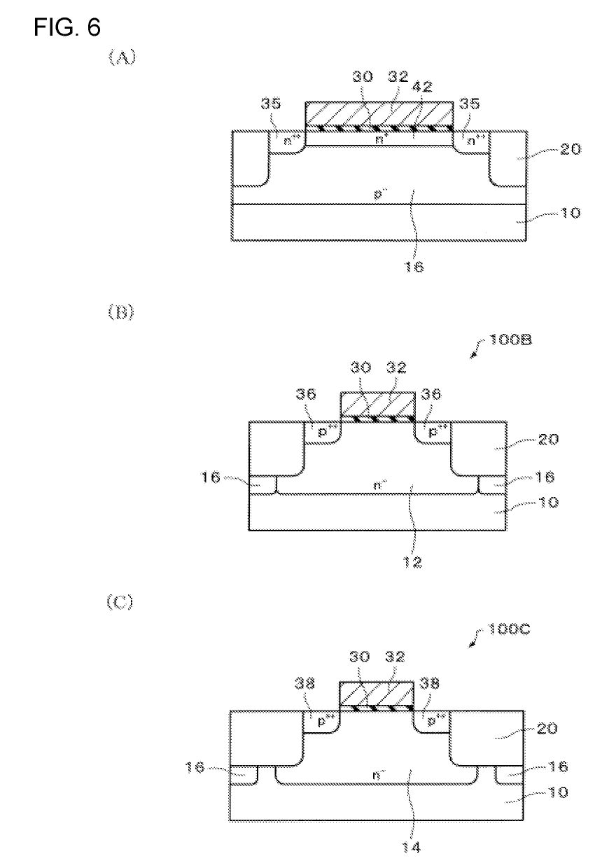

Next, the second example of the first embodiment will be described in reference with FIG. 4 and 6. The semiconductor device according to the second example is an example which the structure of the control gate section is different compared to the first example. More specifically, in the semiconductor device according to the second example, the difference from the first embodiment is that the N-type impurity region provided under the floating gate electrode 32 is made to be the control gate. FIG. 4 is a perspective view showing the memory cell C100 included in the semiconductor device according to the present embodiment. FIG. 5 is a plan view showing the disposition of the floating gate electrode 32 and various impurity regions in the memory cell C100. FIG. 6A is a cross section taken along the line A-A of FIG. 5. FIG. 6B is a cross section taken along the line B-B of FIG. 5. FIG. 6C is a cross section taken along the line C-C of FIG. 5. Further, for a similar structure and a similar member to the first embodiment, a detailed description is omitted.

As shown in FIG. 4, the semiconductor device according to the second example is provided on the semiconductor layer 10 of P-type as in the case of the semiconductor device according to the first example. The semiconductor layer 10 is isolated and defined into the region 10A, the region 10B, and the region 10C by the isolation insulating layer 20. The well 16 of P-type is provided in the region 10A, the well 12 of N-type is provided in the region 10B, and the well 14 of N-type is provided in the region 10C. The well 14 of N-type and the well 16 of P-type are disposed spaced apart. In other words, the semiconductor layer 10, which is a substrate, is provided at a boundary between the well 14 of N-type and the well 16 of P-type. Further, as in the case of the first embodiment, the region 10A is the control gate section, the region 10B is the write section, and the region 10C is the erase section.

As shown in FIGS. 4 and 5, in the memory cell according to the second example, a pattern of the floating gate electrode 32 is different from that of the first example. More specifically, the region 10A is disposed between the region 10B and the region 10C. Therefore, the region 10A also functions as isolating the region 10B and the region 10C. Being disposed in such a way, the floating gate electrode 32 has a pattern which the pattern of the center portion (a part provided above the control gate section) is being partially large. In other words, it has the pattern that the protruded part is provided in the region 10A.

As shown in FIG. 4, the insulating layer 30 is provided on the semiconductor layer 10 in the regions 10A to 10C. On the insulating layer 30, the floating gate electrode 32 is provided across the regions 10A to 10C. In the region 10A, as shown in FIGS. 4 and 5, impurity regions 35 of N-type are provided so as to sandwich the floating gate electrode 32 in between. In the region 10B, the impurity regions 36 of P-type are provided so as to sandwich the floating gate electrode 32 in between. In the region 10C, the impurity regions 38 of N-type are provided so as to sandwich the floating gate electrode 32 in between.

Next, the cross sectional structure of each region will be described in reference with FIGS. 6A and 6C.

As shown in FIG. 6A, the region 10A has the insulating layer 30 provided on the well 16 of P-type, the floating gate electrode 32 provided on the insulating layer 30 and the impurity regions 35. The impurity regions 35 may be the contact portion to an impurity region (control gate) 42 of N-type. As shown in FIG. 6B, in the region 10B, the MOS transistor 100B of P-channel type is provided to perform the write to the memory cell C100. The same applies for the MOS transistor 100B of P-channel type as in the case of the first example. As shown in FIG. 6C, in the region 10C, the transistor 100C of P-channel type is provided. The same applies for the transistor 100C of P-channel type as in the case of the MOS transistor 100C of P-channel described in the first example.

In the semiconductor device according to the first embodiment, the MOS transistor 100C of P-channel which is used during the erase period (releasing electrons injected into the floating gate electrode 32) is provided in the well 14 of N-type spaced apart from the wells 16 and 17 of P-type. Therefore, the semiconductor layer 10 of P-type, which is the substrate itself, is provided at the periphery of the well 14 of N-type. The semiconductor layer 10 of P-type, which is the substrate, has low impurity concentration compared to the wells 16 and 17 of P-type, which enables to minimize the junction capacitance between the well 14 of N-type and the semiconductor layer 10 of P-type, and eventually enables to increase the breakdown voltage of the well 14 of N-type. Herewith, a high voltage may be applied during the erase period, which enables to reduce the erase time. As a result, the semiconductor device including the memory cell C100 with improved erase characteristics can be provided.

Further, in the semiconductor device according to the second example, the first impurity region 42 of N-type under the floating gate electrode 32 in the region 10A functions as the control gate. Therefore, miniaturization can be achieved compared to the semiconductor device according to the first example which the whole well 12 of N-type is the control gate.

Furthermore, although the well 12 of N-type and the well 14 of N-type have the same conductivity type, because the voltage applied to each well is different, the wells may not be used in common. In such a case, a well isolation region needs to be provided. In the semiconductor device according to the second example, as the region 10A also functions as the well isolation between the well 12 of N-type and the well 14 of N-type, further miniaturization can be achieved.

### 2. The Second Embodiment

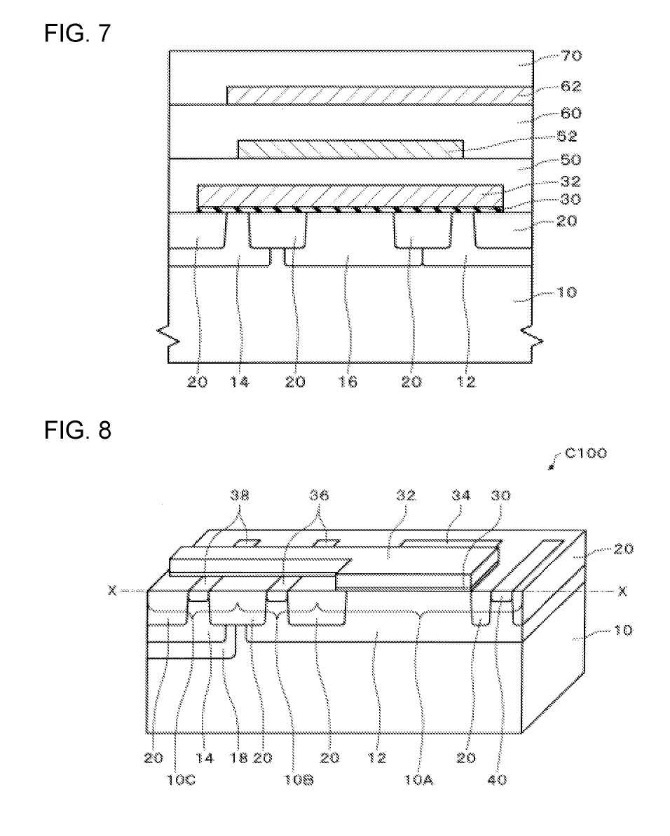

Next, the semiconductor device according to the second embodiment will be described in reference with FIG. 7. FIG. 7 is a cross sectional view schematically showing the semiconductor device according to the second embodiment and showing a cross section taken along the line I-I of FIG. 5. Further, the semiconductor device according to the second embodiment is an example of providing an inversion preventing layer above the spaced apart portion between the wells 16 and 17 of P-type adjacent to the well 14 of N-type in the semiconductor device according to the second example of the first embodiment.

In the semiconductor device according to the second embodiment, as shown in FIG. 7, a first interlayer insulating layer 50, a second interlayer insulating layer 60, and a third interlayer insulating layer 70 are sequentially provided above the memory cell C100 so as to cover the floating gate electrode 32. The first layer of a conductive layer (wiring layer) 52 is provided on the first interlayer insulating layer 50 and the second layer of a conductive layer (wiring layer) 62 is provided on the second interlayer insulating layer 60.

The conductive layer 62, although not shown in the cross sectional view shown in FIG. 7, is electrically connected to the transistor 100C of P-channel type in the region 10C, and used as an erase signal line. On the other hand, the conductive layer 52 is connected to a ground (GND) and has a predetermined pattern so as to be provided at least above the spaced apart portion. More specifically, because the well 14 of N-type and the wells 16 and 17 of P-type are spaced apart, the conductive layer 52 is provided so as to cover the semiconductor layer 10 (hereinafter may be referred to as a ‘spaced apart portion’) in which the impurity likely to generate will not be injected. Therefore, a portion of the conductive layer 52 which covers the spaced apart portion functions as the inversion preventing layer.

The semiconductor device according to the second embodiment has the same advantage as the semiconductor device according to the first embodiment, and can provide the semiconductor device with improved erase characteristics. Further, as the conductive layer 52, which is connected to the ground, covers the spaced apart portion, which enables to prevent the semiconductor layer 10 to be inverted and generate a leak path even if the high voltage is applied for erasing. Furthermore, as the erase signal line is configured in the second layer of the conductive layer 62, a certain gap may be provided between the semiconductor layer 10 and the conductive layer 62, which further enhance the effect of the inversion prevention. As a result, the semiconductor device, while maintaining the reliability, enables to increase the erase voltage and reduce the erase time can be provided.

Meanwhile, in the second embodiment, the case which the inversion preventing layer is provided to the second example of the first embodiment was described, but it is not limited to this, and may apply to the semiconductor device according to the first example of the first embodiment. In this case, the conductive layer 52 is to be provided in the spaced apart portion between the well 14 of N-type and the well 17 of P-type. Also, as the erase signal line, the case using the second layer of the conductive layer 62 was described, but it is not limited to this, and may use the conductive layer of the third layer or above.

### 3. The Third Embodiment

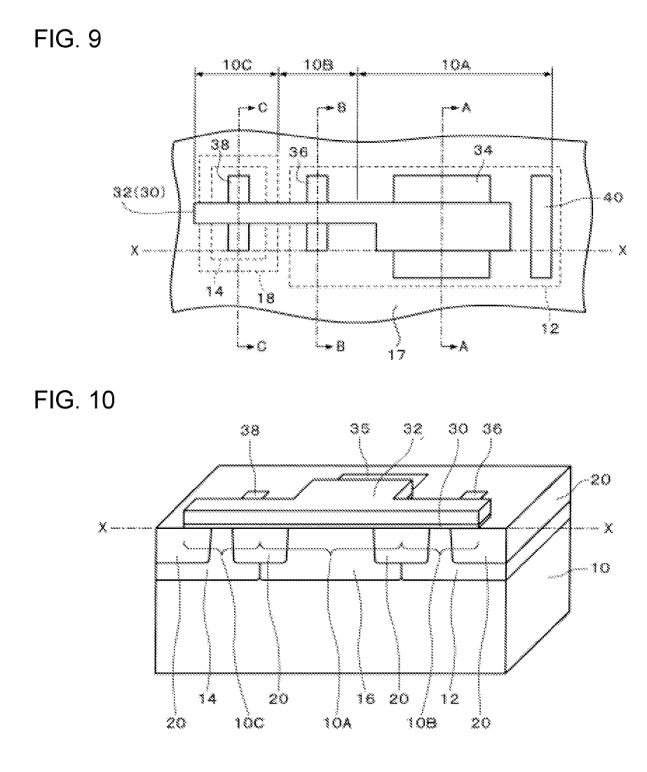

Next, the semiconductor device according to the third embodiment will be described in reference with FIGS. 8 and 9. FIG. 8 is a perspective view schematically showing the semiconductor device according to the third embodiment, and FIG. 9 is a plan view schematically showing a positional relationship between the floating gate electrode 32 and various impurity regions. Further, in the third embodiment, the difference to the first embodiment will be described by using the memory cell C100, which has the same structure as the above described semiconductor device according to the first example of the first embodiment, as an example.

In the third embodiment, the difference is that a low concentration impurity layer 18 of N-type (corresponding to a ‘fourth diffused layer’) is provided so as to surround the well 14 of N-type in the region 10C. The low concentration impurity layer 18 is the layer that the impurity concentration is lower compared to the well 14 of N-type. Further, the low concentration impurity layer 18 may be formed by the same forming process as the low concentration impurity layer (drain over or drain offset) which surrounds the drain region of a high breakdown voltage MOS transistor (not shown) that is consolidated on the semiconductor layer 10, which is identical to the memory cell C100 according to the present embodiment.

In the semiconductor device according to the third embodiment, the MOS transistor 100C of P-channel used during the erase period is provided in the well 14 of N-type of which the low concentration impurity layer 18 is disposed at the periphery. This enables to increase the breakdown voltage of the well 14 of N-type, and may apply the high voltage during the erase period. Therefore, the erase time can be reduced. As a result, the semiconductor device including the non-volatile memory element with improved erase characteristics can be provided. Further, in the third embodiment, the example of providing the low concentration impurity layer 18 to the semiconductor device according to the first example of the first embodiment was described, but it is not limited to this, and may be applied to the semiconductor device according to the second example of the first embodiment.

### 4. The Fourth Embodiment

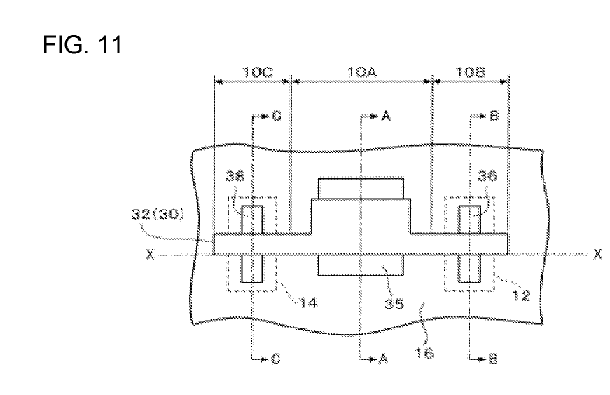

Next, the semiconductor device according to the fourth embodiment will be described in reference with FIGS. 10 and 11. FIG. 10 is a perspective view schematically showing the semiconductor device according to the fourth embodiment, and FIG. 11 is a plan view schematically showing the positional relationship between the floating gate electrode 32 and various impurity regions. Further, in the fourth embodiment, the difference to the first embodiment will be described by using a similar structure as the above described semiconductor device according to the second example of the first embodiment as an example.

In the semiconductor device according the fourth embodiment, the impurity concentrations of the well 12 of N-type in the region 10B and the well 14 of N-type in the region 10C are different. More specifically, the impurity concentration of the well 14 of N-type is lower compared to the well 12 of N-type.

In the semiconductor device according to the fourth embodiment, the MOS transistor 100C of P-channel used during the erase period is provided in the well 14 of N-type which has the lower impurity concentration compared to the well 12 of N-type provided in the MOS transistor 100B of P-channel. Therefore, the well 14 of N-type can reduce the junction capacitance to the adjacent P-type semiconductor region compared to the well 12 of N-type. This enables to apply the high voltage value during the erase period, which enables to reduce the erase time. As a result, the semiconductor device including the non-volatile memory element with improved erase characteristics can be provided. Further, in the fourth embodiment, the case which the present embodiment is applied to the semiconductor device according to the second example of the first embodiment was described, but it is not limited to this, and may be applied to the semiconductor device according to the first example of the first embodiment.

In addition, the present invention is not limited to the above embodiments, but can be modified in various ways. For example, the invention includes a structure substantially the same as the structure described in the embodiments (for example, a structure with the same function, method, and result, or a structure with the same object and effect). Further, the invention includes a structure that a non-essential part is replaced from the structure described in the embodiment. Furthermore, the invention includes a structure that can result in the same effect or a structure that can achieve the same object as the structure described in the embodiment. Also, the invention includes a structure that a known art is added to the structure described in the embodiment.

What is claimed is:

1. A semiconductor device, comprising:
a non-volatile memory element,
the non-volatile memory element includes:
a first region;
a second region formed adjacent to the first region; and
a third region formed adjacent to the second region; and
the non-volatile memory element further includes:
a semiconductor layer;
an isolation insulating layer provided on the semiconductor layer and defines a forming region of the non-volatile memory element;
a first diffused layer formed on the semiconductor layer in the first region;
a first source region and a first drain region formed on the first diffused layer;
a second diffused layer spaced apart from the first diffused layer and formed on the semiconductor layer at a periphery of the first diffused layer and the second region;
a third diffused layer formed on the semiconductor layer in the third region;
a second source region and a second drain region formed on the third diffused layer;
a first insulating layer formed above the semiconductor layer in the forming region of the non-volatile memory element; and
a first conductive layer provided above the first insulating layer.

2. The semiconductor device according to claim 1, wherein
the first diffused layer has a first conductivity type; and
the second diffused layer has a second conductivity type.

3. The semiconductor device according to claim 2, wherein
the first source region and the first drain region have a second conductivity type; and
the second source region and the second drain region have the second conductivity type.

4. The semiconductor device according to claim 3, wherein the third diffused layer has the first conductivity type.

5. The semiconductor device according to claim 1, wherein the first conductive layer has a protruded part in the second region.

6. The semiconductor device according to claim 1, further comprising a fourth diffused layer having an impurity concentration lower than the first diffused layer, being formed so as to surround the first diffused layer.

7. The semiconductor device according to claim 6, wherein the fourth diffused layer is spaced apart from the second diffused layer.

8. The semiconductor device according to claim 6, wherein the fourth diffused layer has the first conductivity type.

9. The semiconductor device according to claim 1, further comprising:
a second insulating layer formed above the first conductive layer; and
a second conductive layer formed above a region between the first diffused layer and the second diffused layer, and above the second insulating layer.

10. A semiconductor device, comprising:
a non-volatile memory element,
the non-volatile memory element includes:
a first region;
a second region formed adjacent to the first region; and
a third region formed adjacent to the second region; and
the non-volatile memory element further includes:
a semiconductor layer;
an isolation insulating layer provided on the semiconductor layer and defines a forming region of the non-volatile memory element;
a first diffused layer formed on the semiconductor layer in the first region;
a first source region and a first drain region formed on the first diffused layer;
a second diffused layer formed on the semiconductor layer in the second region;
a third diffused layer formed on the semiconductor layer in the third region and the impurity concentration being higher than the first diffused layer;
a second source region and a second drain region formed on the third diffused layer;
a first insulating layer formed above the semiconductor layer in the forming region of the non-volatile memory element; and
a first conductive layer provided above the first insulating layer.

11. The semiconductor device according to claim 10, wherein
the first diffused layer has a first conductivity type;
the first source region and the first drain region have a second conductivity type;
the second diffused layer has the second conductivity type;
the third diffused layer has the first conductivity type; and
the second source region and the second drain region have the second conductivity type.

12. The semiconductor device according to claim 11, wherein the third diffused layer has the first conductivity type.

13. The semiconductor device according to claim 10, wherein the first conductive layer has a protruded part in the second region.

14. The semiconductor device according to claim 10, wherein the first diffused layer is in contact with the second diffused layer.

15. The semiconductor device according to claim 1, wherein
the first conductivity type is an N-type; and
the second conductivity type is a P-type.
